(19) United States
(12) Patent Application Publication
(10) Pub. No.: US 2026/0261265 A1
(43) Pub. Date: Sep. 3, 2026

(54) Time-interleaved analog-to-digital converter

(71) Applicant: REALTEK SEMICONDUCTOR CORPORATION, Hsinchu (TW)

(72) Inventor: SHIH-HSIUNG HUANG, Hsinchu (TW)

(21) Appl. No.: 19/465,098

(22) Filed: Jan. 30, 2026

(30) Foreign Application Priority Data
Feb. 19, 2025 (TW) 114106152

(51) Int. Cl. H03M 1/12

(52) U.S. Cl. CPC H03M 1/1245; H03M 1/1215

(57) ABSTRACT

A time-interleaved analog-to-digital converter (ADC) includes an input terminal, two sampling switches, two sampling capacitors, two buffer circuits, two ADC groups, and two signal paths. The two sampling switches are both coupled to the input terminal and are respectively coupled to their own sampling capacitors. The first buffer circuit is coupled to the first sampling switch and the first sampling capacitor. The second buffer circuit is coupled to the second sampling switch and the second sampling capacitor. The first and second ADC groups are respectively coupled to the first and second buffer circuits. The first signal path is located between the first buffer circuit and the first ADC group. The second signal path is located between the second buffer circuit and the second ADC group. The first and second signal paths have different lengths. The first and second buffer circuits have different driving capabilities.

### BACKGROUND OF THE INVENTION

### 1. Field of the Invention

The present invention generally relates to an analog-to-digital converter (ADC), and more particularly, to a time-interleaved analog-to-digital converter (TIADC).

### 2. Description of Related Art

The conventional TIADC includes multiple ADC groups and multiple sampling switches (one sampling switch corresponds to one ADC group), and each ADC group contains multiple ADCs. Due to the increasing number of functions, complexity, and decreasing size of today's integrated circuits (ICs), it becomes increasingly difficult to achieve an ideal circuit arrangement within a limited circuit area. More specifically, the multiple signal paths between the multiple sampling switches and the corresponding ADC groups are very likely to be of unequal length, and signal paths of unequal length usually come with mismatched impedances. Therefore, the characteristics (e.g., phase, degree of attenuation, etc.) of the multiple sampled signals corresponding to the ADC groups differ so greatly that they cause time-interleaved errors in the TIADC.

### SUMMARY OF THE INVENTION

In view of the issues of the prior art, an object of the present invention is to provide a TIADC, so as to make an improvement to the prior art.

According to one aspect of the present invention, a TIADC is provided. The TIADC includes an input terminal, a first sampling switch, a second sampling switch, a first sampling capacitor, a second sampling capacitor, a first buffer circuit, a second buffer circuit, a first ADC group, a second ADC group, a first signal path, and a second signal path. The first sampling switch is coupled to the input terminal. The second sampling switch is coupled to the input terminal. The first sampling capacitor is coupled to the first sampling switch. The second sampling capacitor is coupled to the second sampling switch. The first buffer circuit is coupled to the first sampling switch and the first sampling capacitor. The second buffer circuit is coupled to the second sampling switch and the second sampling capacitor. The first ADC group is coupled to the first buffer circuit. The second ADC group is coupled to the second buffer circuit. The first signal path is coupled between the first buffer circuit and the first ADC group. The second signal path is coupled between the second buffer circuit and the second ADC group. A first length of the first signal path is not equal to a second length of the second signal path, and a first driving capability of the first buffer circuit is not equal to a second driving capability of the second buffer circuit.

According to another aspect of the present invention, a TIADC is provided. The TIADC includes an input terminal, a first sampling switch, a second sampling switch, a first sampling capacitor, a second sampling capacitor, a first buffer circuit, a second buffer circuit, a first ADC group, a second ADC group, a first signal path, a second signal path, a first load, and a second load. The first sampling switch is coupled to the input terminal. The second sampling switch is coupled to the input terminal. The first sampling capacitor is coupled to the first sampling switch. The second sampling capacitor is coupled to the second sampling switch. The first buffer circuit is coupled to the first sampling switch and the first sampling capacitor. The second buffer circuit is coupled to the second sampling switch and the second sampling capacitor. The first ADC group is coupled to the first buffer circuit. The second ADC group is coupled to the second buffer circuit. The first signal path is coupled between the first buffer circuit and the first ADC group. The second signal path is coupled between the second buffer circuit and the second ADC group. The first load is coupled to the first signal path. The second load is coupled to the second signal path. A first length of the first signal path is not equal to a second length of the second signal path, and a first impedance of the first load is not equal to a second impedance of the second load.

According to still another aspect of the present invention, a TIADC is provided. The TIADC includes an input terminal, a first buffer circuit, a second buffer circuit, a first signal path, a second signal path, a first analog-to-digital converter group, a second analog-to-digital converter group, a first sampling switch, a second sampling switch, a first sampling capacitor, and a second sampling capacitor. The first signal path is coupled between the input terminal and the first buffer circuit. The second signal path is coupled between the input terminal and the second buffer circuit. The first analog-to-digital converter group is coupled to the first buffer circuit. The second analog-to-digital converter group is coupled to the second buffer circuit. The first sampling switch is disposed on the first signal path and coupled to the input terminal and the first buffer circuit. The second sampling switch is disposed on the second signal path and coupled to the input terminal and the second buffer circuit. The first sampling capacitor is coupled to the first sampling switch. The second sampling capacitor is coupled to the second sampling switch. A first length of the first signal path is not equal to a second length of the second signal path, and a first turn-on duration of the first sampling switch is not equal to a second turn-on duration of the second sampling switch.

The technical means embodied in the embodiments of the present invention can solve at least one of the problems of the prior art. Therefore, compared to the prior art, the present invention can avoid or reduce time-interleaved errors.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 is the circuit diagram of a TIADC according to an embodiment of the present invention.

FIG. 2 is the circuit diagram of a TIADC according to another embodiment of the present invention.

FIG. 3 is the circuit diagram of the loads in FIG. 2 according to an embodiment.

FIG. 4 is the circuit diagram of the loads in FIG. 2 according to another embodiment.

FIG. 5 is the circuit diagram of a TIADC according to another embodiment of the present invention.

FIG. 6 shows the waveforms of multiple clocks of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes a TIADC. On account of that some or all elements of the TIADC could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

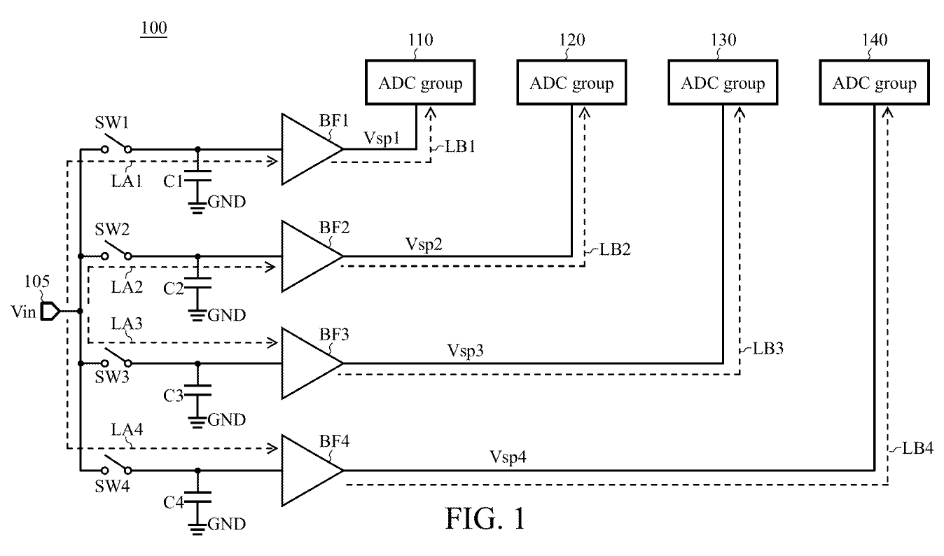

Reference is made to FIG. 1, which is the circuit diagram of a TIADC according to an embodiment of the present invention. The TIADC 100 includes ADC groups 110 to 140, sampling switches SW1 to SW4, sampling capacitors C1 to C4, and buffer circuits BF1 to BF4. The ADC groups 110 to 140 each contain multiple ADCs.

One terminal of the sampling switch SW1 (SW2, SW3, SW4) is coupled or electrically connected to an input terminal 105; another terminal of the sampling switch SW1 (SW2, SW3, SW4) is coupled or electrically connected to the input terminal of the buffer circuit BF1 (BF2, BF3, BF4).

One terminal of the sampling capacitor C1 (C2, C3, C4) is coupled or electrically connected to both the sampling switch SW1 (SW2, SW3, SW4) and the input terminal of the buffer circuit BF1 (BF2, BF3, BF4); the other terminal of the sampling capacitor C1 (C2, C3, C4) is coupled or electrically connected to a reference voltage GND (e.g., ground).

The ADC group 110 (120, 130, 140) is coupled or electrically connected to the output terminal of the buffer circuit BF1 (BF2, BF3, BF4).

The sampling switch SW1, the sampling switch SW2, the sampling switch SW3, and the sampling switch SW4 are turned on sequentially to sample the input signal Vin, thereby generating the sampled signal Vsp1, the sampled signal Vsp2, the sampled signal Vsp3, and the sampled signal Vsp4, respectively.

The operating principle of the TIADC 100 is well known to people having ordinary skill in the art, so further elaboration is omitted for brevity. The number of ADC groups in FIG. 1 is intended to illustrate the invention by way of example, rather than to limit the scope of the claimed invention. In an alternative embodiment, the TIADC 100 includes N ADC groups, N sampling switches, N sampling capacitors and N buffer circuits, where N is an integer greater than or equal to 2.

The signal path LA1 is the signal path between the input terminal 105 and the buffer circuit BF1. The signal path LA2 is the signal path between the input terminal 105 and the buffer circuit BF2. The signal path LA3 is the signal path between the input terminal 105 and the buffer circuit BF3. The signal path LA4 is the signal path between the input terminal 105 and a buffer circuit BF4. The sampling switches SW1 to SW4 are respectively disposed on the signal paths LA1 to LA4.

The signal path LB1 is the signal path between the buffer circuit BF1 and the ADC group 110. The signal path LB2 is the signal path between the buffer circuit BF2 and the ADC group 120. The signal path LB3 is the signal path between the buffer circuit BF3 and the ADC group 130. The signal path LB4 is the signal path between the buffer circuit BF4 and the ADC group 140.

In the following discussion, in terms of length, it is assumed that LA1 < LA2 < LA3 < LA4, and LB1 < LB2 < LB3 < LB4.

The output terminal of the buffer circuit BF1 (BF2, BF3, BF4) is coupled or electrically connected to the ADC group 110 (120, 130, 140) and outputs the sampled signal Vsp1 (Vsp2, Vsp3, Vsp4). More specifically, the buffer circuits BF1 to BF4 are used to increase the magnitude of the charge or discharge currents of the sampled signals Vsp1 to Vsp4 on the corresponding signal paths LB1 to LB4, respectively. Additionally, the driving capabilities of the buffer circuits BF1 to BF4 are not exactly the same. For example, the longer the signal path, the greater the driving capability required of the corresponding buffer circuit. That is to say, because LB1 < LB2 < LB3 < LB4, the driving capabilities of the buffer circuits BF1 to BF4 can be designed such that BF4 > BF3 > BF2 > BF1. In this way, it is able to reduce time-interleaved errors in the TIADC 100.

The buffer circuit includes at least one Metal-Oxide-Semiconductor Field-Effect Transistor (MOSFET). In some embodiments, the driving capability of a buffer circuit can be enhanced by increasing the area of the MOSFET. In an alternative embodiment, the driving capability of a buffer circuit can be enhanced by connecting multiple MOSFETs in parallel.

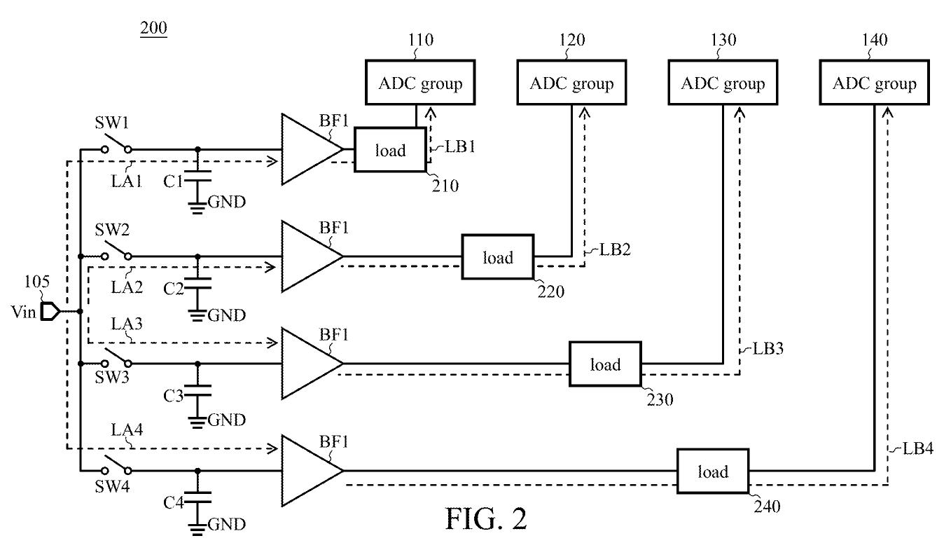

Reference is made to FIG. 2, which is the circuit diagram of a TIADC according to another embodiment of the present invention. The TIADC 200 is similar to the TIADC 100, except that the signal paths LB1 to LB4 are respectively additionally provided with a load 210, a load 220, a load 230, and a load 240, and the four buffer circuits BF1 are substantially identical (more specifically, having substantially the same driving capability). Note that the loads 210 to 240 are additional loads, and not the loads of the signal paths LB1 to LB4 themselves. The embodiment of FIG. 2 addresses the time-interleaved error by adjusting the load on the signal path. More specifically, the longer the signal path (LB1 to LB4) is, the smaller the impedance of the corresponding load (210 to 240) is adjusted to.

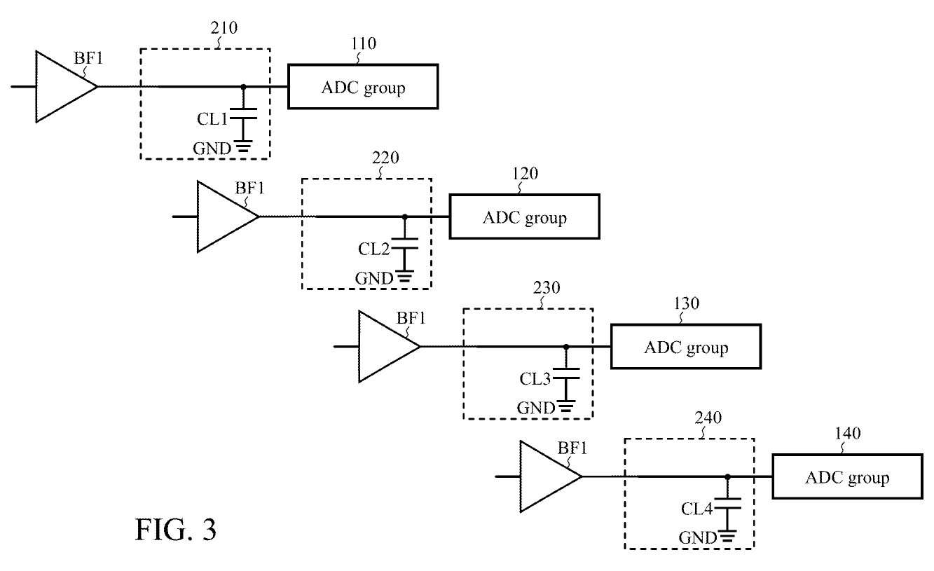

Reference is made to FIG. 3, which is a circuit diagram of the loads in FIG. 2 according to an embodiment. The loads 210 to 240 respectively include the load capacitors CL1 to CL4. One terminal of the load capacitor CL1 (CL2, CL3, CL4) is coupled or electrically connected to both the output terminal of the buffer circuit BF1 (BF2, BF3, BF4) and the input terminal of the ADC group 110 (120, 130, 140); the other terminal of the load capacitor CL1 (CL2, CL3, CL4) is coupled or electrically connected to the reference voltage GND. Because in terms of length LB1 < LB2 < LB3 < LB4, the load capacitors are adjusted such that CL1 > CL2 > CL3 > CL4 in terms of capacitance value.

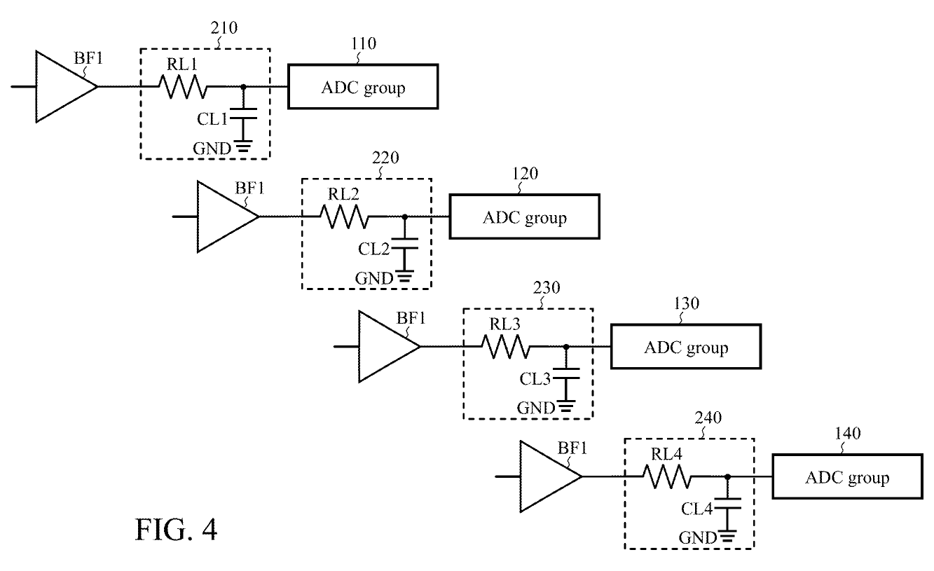

Reference is made to FIG. 4, which is the circuit diagram of the loads in FIG. 2 according to another embodiment. The load 210 includes the load capacitor CL1 and a resistor RL1. The load 220 includes the load capacitor CL2 and a resistor RL2. The load 230 includes the load capacitor CL3 and a resistor RL3. The load 240 includes the load capacitor CL4 and a resistor RL4. One terminal of the resistor RL1 (RL2, RL3, RL4) is coupled or electrically connected to the output terminal of the buffer circuit BF1 (BF2, BF3, BF4); the other terminal of the resistor RL1 (RL2, RL3, RL4) is coupled or electrically connected to the input terminal of the ADC group 110 (120, 130, 140). Because in terms of length LB1 < LB2 < LB3 < LB4, the load capacitors are adjusted such that CL1 > CL2 > CL3 > CL4 in terms of capacitance value, or the resistors are adjusted such that RL1 > RL2 > RL3 > RL4 in terms of resistance value, or both the capacitance values and the resistance values are adjusted to satisfy CL1 > CL2 > CL3 > CL4 and RL1 > RL2 > RL3 > RL4.

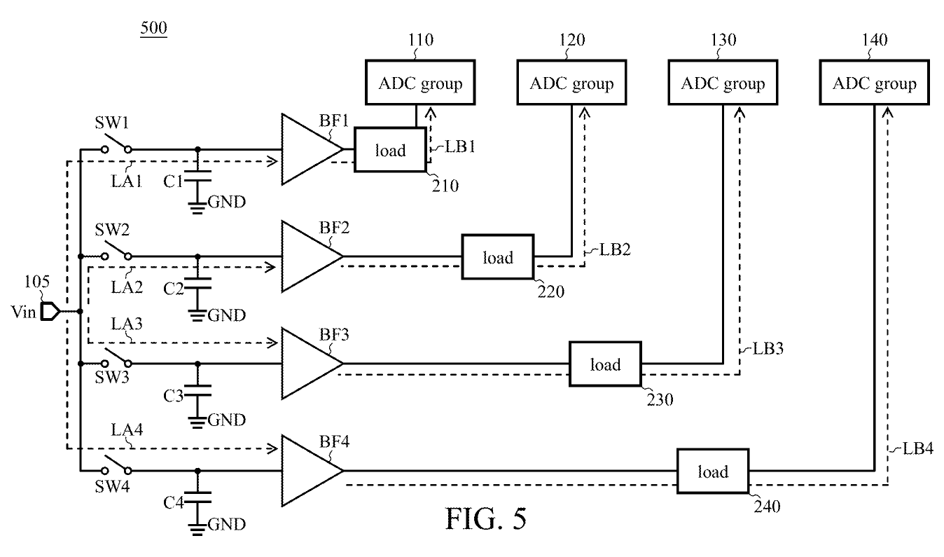

Reference is made to FIG. 5, which is the circuit diagram of the TIADC according to another embodiment of the present invention. The TIADC 500 is a combination of the TIADC 100 and the TIADC 200. More specifically, the driving capabilities of the four buffer circuits (BF1 to BF4) are not exactly the same, and each buffer circuit is coupled or electrically connected to a load (210 to 240). People having ordinary skill in the art can understand the operational details of the TIADC 500 based on the discussion of FIGS. 1 and 2, so further elaboration is omitted for brevity.

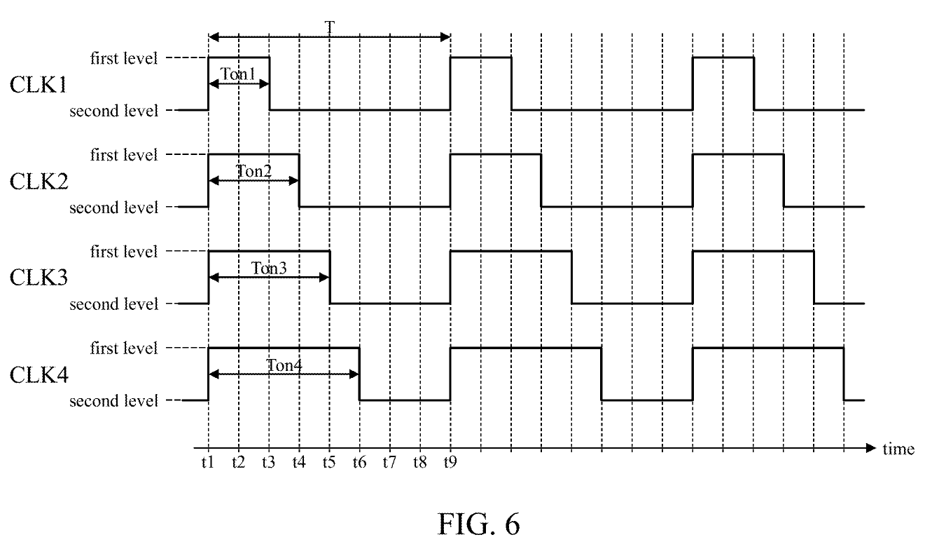

For the mismatch between the signal paths LA1 to LA4 (caused by different degrees of signal attenuation resulting from varying lengths), the following solution is proposed. Reference is made to FIG. 6, which shows the waveforms of multiple clocks of the present invention. The sampling switches SW1 to SW4 operate according to the clocks CLK1 to CLK4, respectively. The clocks CLK1 to CLK4 have substantially the same period T. The rising edges of the clocks CLK1 to CLK4 are substantially aligned, while the falling edges (corresponding to the time points t3, t4, t5, and t6, respectively) are spaced by T/(2*N), where N is the number of ADC groups.

When the clock CLK1 (CLK2, CLK3, CLK4) is at the first level (e.g., a high level), the sampling switch SW1 (SW2, SW3, SW4) is turned on. When the clock CLK1 (CLK2, CLK3, CLK4) is at the second level (e.g., a low level), the sampling switch SW1 (SW2, SW3, SW4) is turned off. For example, at the time point t1, the sampling capacitors C1 to C4 start sampling the input signal Vin at substantially the same time, and sequentially complete the sampling operations at the time points t3 to t6, respectively. Meanwhile, the ADC groups 110 to 140 sequentially initiate the analog-to-digital conversion operations at the time points t3 to t6, respectively. That is to say, Ton1 < Ton2 < Ton3 < Ton4, where Ton1 to Ton4 are the turn-on durations of the sampling switches SW1 to SW4, respectively. In other words, in terms of duty cycle, CLK1 < CLK2 < CLK3 < CLK4. The longer the signal path (LA1 < LA2 < LA3 < LA4), the longer the turn-on duration of the corresponding sampling switch (Ton1 < Ton2 < Ton3 < Ton4). By adjusting the turn-on duration of the sampling switch (i.e., adjusting the length of the sampling time), this disclosure compensates for the signal quality differences caused by unequal signal path lengths, thereby reducing the time-interleaved error.

If the ADC group 110 (120, 130, 140) contains M ADCs (where M is an integer greater than 1), then the M ADCs operate sequentially during the 1^{st} to the M^{th} cycles of the clock CLK1 (CLK2, CLK3, CLK4), then operate sequentially during the (M+1)^{th} to the (2M)^{th} cycles of the clock CLK1 (CLK2, CLK3, CLK4), and so on. People having ordinary skill in the art can implement a TIADC based on the above discussion, so further elaboration is omitted for brevity.

The clocks CLK1 to CLK4 in FIG. 6 can be applied to the TIADC 100, the TIADC 200, and the TIADC 500.

In the following description, signals are active-high, which means that signals are active at high levels and inactive at low levels, and that asserting/de-asserting a signal means setting the signal high/low. This is for the purpose of explanation, not for limiting the scope of the invention. In other words, in an alternative implementation, signals can be active-low, which means that signals are active at low levels and inactive at high levels, and that asserting/de-asserting a signal means setting the signal low/high. A level transition or a logic level transition means that a signal changes from an asserted (active) state to a de-asserted (inactive) state, or from a de-asserted (inactive) state to an asserted (active) state.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A time-interleaved analog-to-digital converter (TIADC), comprising:
an input terminal;
a first sampling switch coupled to the input terminal;
a second sampling switch coupled to the input terminal;
a first sampling capacitor coupled to the first sampling switch;
a second sampling capacitor coupled to the second sampling switch;
a first buffer circuit coupled to the first sampling switch and the first sampling capacitor;
a second buffer circuit coupled to the second sampling switch and the second sampling capacitor;
a first analog-to-digital converter (ADC) group coupled to the first buffer circuit;
a second ADC group coupled to the second buffer circuit;
a first signal path coupled between the first buffer circuit and the first ADC group; and
a second signal path coupled between the second buffer circuit and the second ADC group;
wherein a first length of the first signal path is not equal to a second length of the second signal path, and a first driving capability of the first buffer circuit is not equal to a second driving capability of the second buffer circuit.

2. The TIADC of claim 1, wherein the first length is less than the second length, and the first driving capability is less than the second driving capability.

3. The TIADC of claim 1, further comprising:
a first load coupled to the first signal path; and
a second load coupled to the second signal path;
wherein a first impedance of the first load is not equal to a second impedance of the second load.

4. The TIADC of claim 3, wherein the first load comprises a first load capacitor, the second load comprises a second load capacitor; the first length is less than the second length; and a first capacitance value of the first load capacitor is greater than a second capacitance value of the second load capacitor.

5. The TIADC of claim 4, wherein the first load further comprises a first resistor; the second load further comprises a second resistor; and a first resistance value of the first resistor is greater than a second resistance value of the second resistor.

6. The TIADC of claim 3, further comprising:
a third signal path coupled between the input terminal and the first buffer circuit; and
a fourth signal path coupled between the input terminal and the second buffer circuit;
wherein the first sampling switch is disposed on the third signal path; the second sampling switch is disposed on the fourth signal path; a third length of the third signal path is not equal to a fourth length of the fourth signal path; and a first turn-on duration of the first sampling switch is not equal to a second turn-on duration of the second sampling switch.

7. The TIADC of claim 6, wherein the third length is less than the fourth length, and the first turn-on duration is less than the second turn-on duration.

8. The TIADC of claim 6, wherein the first sampling switch operates according to a first clock; the second sampling switch operates according to a second clock; the first clock and the second clock have substantially a same period but different duty cycles.

9. The TIADC of claim 1, further comprising:
a third signal path coupled between the input terminal and the first buffer circuit; and
a fourth signal path coupled between the input terminal and the second buffer circuit;
wherein the first sampling switch is disposed on the third signal path; the second sampling switch is disposed on the fourth signal path; a third length of the third signal path is not equal to a fourth length of the fourth signal path; and a first turn-on duration of the first sampling switch is not equal to a second turn-on duration of the second sampling switch.

10. A time-interleaved analog-to-digital converter (TIADC), comprising:
an input terminal;
a first sampling switch coupled to the input terminal;
a second sampling switch coupled to the input terminal;
a first sampling capacitor coupled to the first sampling switch;
a second sampling capacitor coupled to the second sampling switch;
a first buffer circuit coupled to the first sampling switch and the first sampling capacitor;
a second buffer circuit coupled to the second sampling switch and the second sampling capacitor;
a first analog-to-digital converter (ADC) group coupled to the first buffer circuit;
a second ADC group coupled to the second buffer circuit;
a first signal path coupled between the first buffer circuit and the first ADC group;
a second signal path coupled between the second buffer circuit and the second ADC group;
a first load coupled to the first signal path; and
a second load coupled to the second signal path;
wherein a first length of the first signal path is not equal to a second length of the second signal path, and a first impedance of the first load is not equal to a second impedance of the second load.

11. The TIADC of claim 10, wherein the first load comprises a first load capacitor, the second load comprises a second load capacitor; the first length is less than the second length; and a first capacitance value of the first load capacitor is greater than a second capacitance value of the second load capacitor.

12. The TIADC of claim 11, wherein the first load capacitor is coupled between the first buffer circuit and a reference voltage, and the second load capacitor is coupled between the second buffer circuit and the reference voltage.

13. The TIADC of claim 11, wherein the first load further comprises a first resistor; the second load further comprises a second resistor; and a first resistance value of the first resistor is greater than a second resistance value of the second resistor.

14. The TIADC of claim 13, wherein the first resistor is coupled between the first buffer circuit and the first ADC group, and the second resistor is coupled between the second buffer circuit and the second ADC group.

15. The TIADC of claim 10, further comprising:
a third signal path coupled between the input terminal and the first buffer circuit; and
a fourth signal path coupled between the input terminal and the second buffer circuit;
wherein the first sampling switch is disposed on the third signal path; the second sampling switch is disposed on the fourth signal path; a third length of the third signal path is not equal to a fourth length of the fourth signal path; and a first turn-on duration of the first sampling switch is not equal to a second turn-on duration of the second sampling switch.

16. The TIADC of claim 15, wherein the third length is less than the fourth length, and the first turn-on duration is less than the second turn-on duration.

17. The TIADC of claim 10, wherein a first driving capability of the first buffer circuit is substantially equal to a second driving capability of the second buffer circuit.

18. A time-interleaved analog-to-digital converter (TIADC), comprising:
an input terminal;
a first buffer circuit;
a second buffer circuit;
a first signal path coupled between the input terminal and the first buffer circuit;
a second signal path coupled between the input terminal and the second buffer circuit;
a first analog-to-digital converter (ADC) group coupled to the first buffer circuit;
a second ADC group coupled to the second buffer circuit;
a first sampling switch disposed on the first signal path and coupled to the input terminal and the first buffer circuit;
a second sampling switch disposed on the second signal path and coupled to the input terminal and the second buffer circuit;
a first sampling capacitor coupled to the first sampling switch; and
a second sampling capacitor coupled to the second sampling switch;
wherein a first length of the first signal path is not equal to a second length of the second signal path, and a first turn-on duration of the first sampling switch is not equal to a second turn-on duration of the second sampling switch.

19. The TIADC of claim 18, wherein the first length is less than the second length, and the first turn-on duration is less than the second turn-on duration.

20. The TIADC of claim 18, wherein the first sampling switch operates according to a first clock; the second sampling switch operates according to a second clock; the first clock and the second clock have substantially a same period but different duty cycles.
